(19) United States
(12) Patent Application Publication
(10) Pub. No.: US 2019/0393271 A1
(43) Pub. Date: Dec. 26, 2019

(54) UP-CONVERSION DEVICE

(71) Applicants: North Carolina State University, Raleigh, NC (US); Nanoholdings, LLC, Rowayton, CT (US)

(72) Inventors: Franky So, Raleigh, NC (US); Ryan Larrabee, Raleigh, NC (US); Nilesh Barange, Raleigh, NC (US); Bhabendra Pradhan, Rowayton, CT (US)

(21) Appl. No.: 16/449,581

(22) Filed: Jun. 24, 2019

Related U.S. Application Data
(60) Provisional application No. 62/688,419, filed on Jun. 22, 2018.

(51) Int. Cl. H01L 27/28; H01L 51/44; H01L 51/50; H01L 51/52; H01L 51/42

(52) U.S. Cl. CPC H01L 27/288; H01L 51/442; H01L 51/5012; H01L 51/5072; H01L 51/424; H01L 51/447; H01L 51/5206; H01L 51/5234; H01L 51/5056

(57) ABSTRACT

An up-conversion device includes a light detecting device and a light emitting device. The light detecting device includes a first electrode, a first electron transport layer, an infrared (IR) sensitizing layer, a first hole transport layer, and a second electrode. The light detecting device receives a first optical signal at a first wavelength. The light emitting device is formed on the light detecting device. The light emitting device shares the second electrode with the light detecting device, and includes a second hole transport layer, a light emitting layer, a second electron transport layer, and a third electrode. The light emitting device outputs a second optical signal at a second wavelength based on the first optical signal and biasing of the light detecting device and the light emitting device.

### CROSS-REFERENCE TO RELATED APPLICATIONS

This application claims priority to U.S. Provisional Patent Application No. 62/688,419 filed on Jun. 22, 2018, the entire contents of which are incorporated by reference herein.

### BACKGROUND

The present invention relates generally to imaging devices, and more particularly to imaging devices including up-conversion devices.

Imaging devices are widely used for capturing images. An imaging device includes an image sensor that senses optical signals reflected from an object which is to be imaged. The image sensor further senses the optical signals in a specific wavelength range. For example, to sense the optical signals in a wavelength range of 350 nanometers (nm) to 1100 nm, a complementary metal oxide semiconductor (CMOS) image sensor or a charge-coupled device (CCD) image sensor may be employed in the imaging device. Similarly, to sense the optical signals in a wavelength range of 900 nm to 2200 nm, an infrared (IR) image sensor may be employed in the imaging device. Thus, neither of the image sensors stated above are individually able to sense the optical signals in the entire wavelength range of 350 to 2200 nm.

To sense the optical signals in the entire wavelength range of 350 to 2200 nm, an IR-to-visible light up-conversion device with a CMOS or CCD image sensor is typically employed in an imaging device. IR-to-visible light up-conversion devices hereinafter referred to as “up-conversion devices”, are devices that convert IR light to visible light. These up-conversion devices have attracted a great deal of research interest because of their potential applications in night vision, see-through fog and smog vision, range detection, security, as well as semiconductor wafer inspections.

An up-conversion device typically includes an anode, a hole blocking layer, an IR sensitizing layer, a hole transport layer, a light emitting layer, an electron transport layer, and a cathode. When an IR light is incident on the IR sensitizing layer, holes and electrons are generated at the IR sensitizing layer. The holes drift towards the light emitting layer by way of the hole transport layer to combine with electrons injected into the light emitting layer by the cathode. The combination of holes and electrons in the light emitting layer results in generation of visible light. The intensity of the visible light is thus based on the combination of the holes and electrons and the intensity of the IR light. In a scenario, where the IR light has low intensity, the sensitivity of the up-conversion device is thus affected. The decrease in the sensitivity of the up-conversion device affects the quality of the image, thereby producing a distorted image.

Hence, it would be advantageous to have an up-conversion device that provides improved sensitivity over conventional up-conversion devices, does not affect image quality when the IR light has low intensity, and overcomes above-mentioned problems of conventional up-conversion devices.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 illustrates an imaging device, in accordance with an embodiment of the present invention;

FIG. 2A illustrates an up-conversion device of the imaging device of FIG. 1, in accordance with an embodiment of the present invention;

FIG. 2B illustrates the up-conversion device of the imaging device of FIG. 1, in accordance with another embodiment of the present invention;

FIG. 2C illustrates the up-conversion device of the imaging device of FIG. 1, in accordance with yet another embodiment of the present invention;

FIG. 2D illustrates the up-conversion device of FIG. 2A including an infrared (IR) pass visible blocking layer, in accordance with yet another embodiment of the present invention;

FIG. 3A illustrates the construction of the imaging device of FIG. 1, in accordance with an embodiment of the present invention;

FIG. 3B illustrates the construction of the imaging device of FIG. 1, in accordance with another embodiment of the present invention;

FIG. 3C illustrates the construction of the imaging device of FIG. 1, in accordance with yet another embodiment of the present invention;

FIG. 4A illustrates a graph showing a current-voltage (I-V) curve of an electrical signal and a biasing voltage of a light emitting device of the up-conversion device of FIGS. 2A-2D for various biasing voltages of a light detecting device of the up-conversion device of FIGS. 2A-2D, in accordance with an embodiment of the present invention; and

FIG. 4B illustrates a graph showing the I-V curve of the electrical signal and a biasing voltage of the light detecting device of the up-conversion device of FIGS. 2A-2D for various biasing voltages of the light emitting device of the up-conversion device of FIGS. 2A-2D, in accordance with an embodiment of the present invention.

### DETAILED DESCRIPTION OF THE PRESENT INVENTION

The detailed description of the appended drawings is intended as a description of the currently preferred embodiments of the present invention and is not intended to represent the only form in which the present invention may be practiced. It is to be understood that the same or equivalent functions may be accomplished by different embodiments that are intended to be encompassed within the spirit and scope of the present invention.

An object of the present invention is to provide an imaging device that includes an up-conversion device.

In one embodiment of the present invention, an up-conversion device is provided. The up-conversion device includes a light detecting device and a light emitting device. The light detecting device includes a first electrode, a first electron transport layer, an infrared (IR) sensitizing layer, a first hole transport layer, and a second electrode. The light detecting device receives a first optical signal at a first wavelength. The light emitting device is formed on the light detecting device. The light emitting device shares the second electrode with the light detecting device, and includes a second hole transport layer, a light emitting layer, a second electron transport layer, and a third electrode. The light emitting device outputs a second optical signal at a second wavelength based on the first optical signal and biasing of the light detecting device and the light emitting device.

In another embodiment of the present invention, an imaging device is provided. The imaging device includes an up-conversion device and an image sensor connected to the up-conversion device. The up-conversion device includes a light detecting device and a light emitting device. The light detecting device includes a first electrode, a first electron transport layer, an infrared (IR) sensitizing layer, a first hole transport layer, and a second electrode. The light detecting device receives a first optical signal at a first wavelength. The light emitting device is formed on the light detecting device. The light emitting device shares the second electrode with the light detecting device, and includes a second hole transport layer, a light emitting layer, a second electron transport layer, and a third electrode. The light emitting device outputs a second optical signal at a second wavelength based on the first optical signal and biasing of the light detecting device and the light emitting device. The image sensor receives the second optical signal and outputs an electrical signal.

Various embodiments of the present invention provide an imaging device. The imaging device includes an up-conversion device and an image sensor connected to the up-conversion device. The up-conversion device includes a light detecting device and a light emitting device. The light detecting device is reverse biased such that first and second electrodes of the light detecting device are cathode and anode, respectively. The light detecting device receives a first optical signal at a first wavelength and generates hole and electron photocurrents. The light emitting device is formed on the light detecting device. The light emitting device shares the second electrode with the light detecting device. The light emitting device is forward biased such that the second electrode is an anode and a third electrode of the light emitting device is a cathode. The light emitting layer receives one of the hole and electron photocurrents and outputs a second optical signal at a second wavelength such that the first wavelength is greater than the second wavelength.

The up-conversion device is a common-base (CB) transistor with the second electrode as a base of the CB transistor, the light detecting device as an emitter of the CB transistor, and the light emitting device as a collector of the CB transistor. Due to the three terminals of the up-conversion device, an improved control over injection of charge carriers, such as holes and electrons, in the light emitting device is achieved as compared to conventional up-conversion devices. Thus, by controlling the injection of charge carriers, a desired amplitude of the electrical signal is achieved. This increases sensitivity of the up-conversion device such that the up-conversion device yields a higher quality image even when the IR light has low intensity.

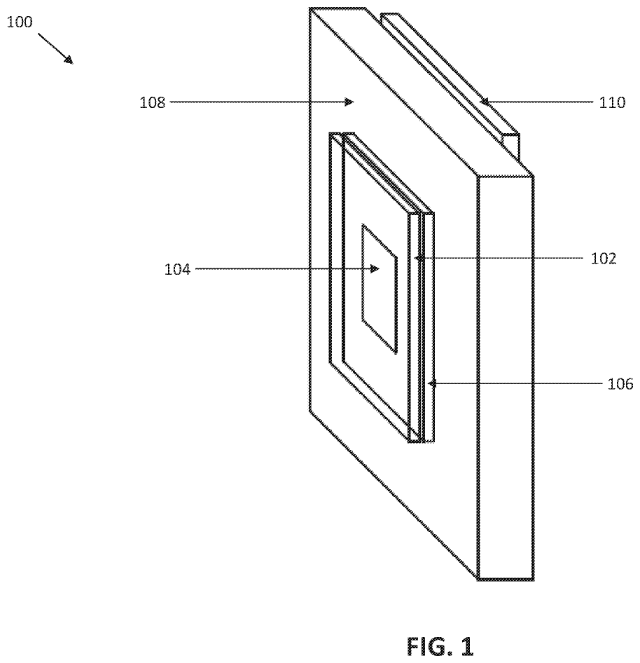

FIG. 1 illustrates an imaging device 100, in accordance with an embodiment of the present invention. In an embodiment, the imaging device 100 is a passive imaging device that measures light radiating from an object to be imaged. In another embodiment, the imaging device 100 is an active imaging device that measures light radiated by an external light source and is reflected or scattered by the object to be imaged.

The imaging device 100 includes an up-conversion device 102 connected to an image sensor 104. In an embodiment, the image sensor 104 is a complementary metal oxide semiconductor (CMOS) image sensor. In another embodiment, the image sensor 104 is a charge-coupled device (CCD) image sensor. The image sensor 104 is attached to a printed circuit board (PCB) 106. The imaging device 100 further includes an electronic system 108 and a display 110.

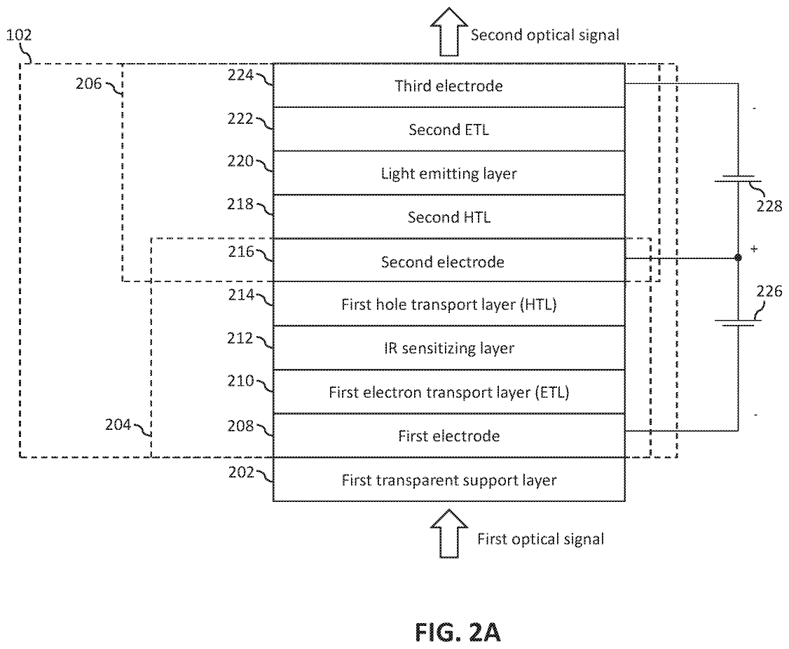

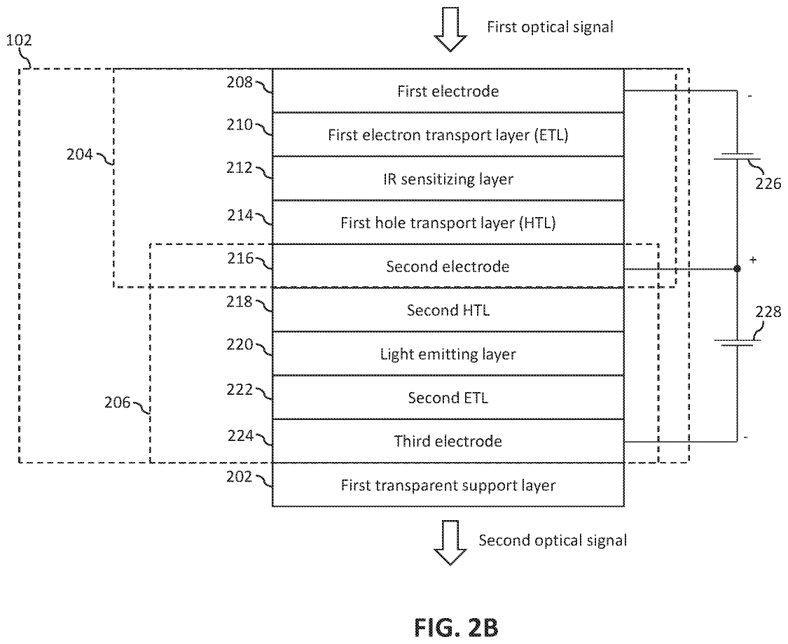

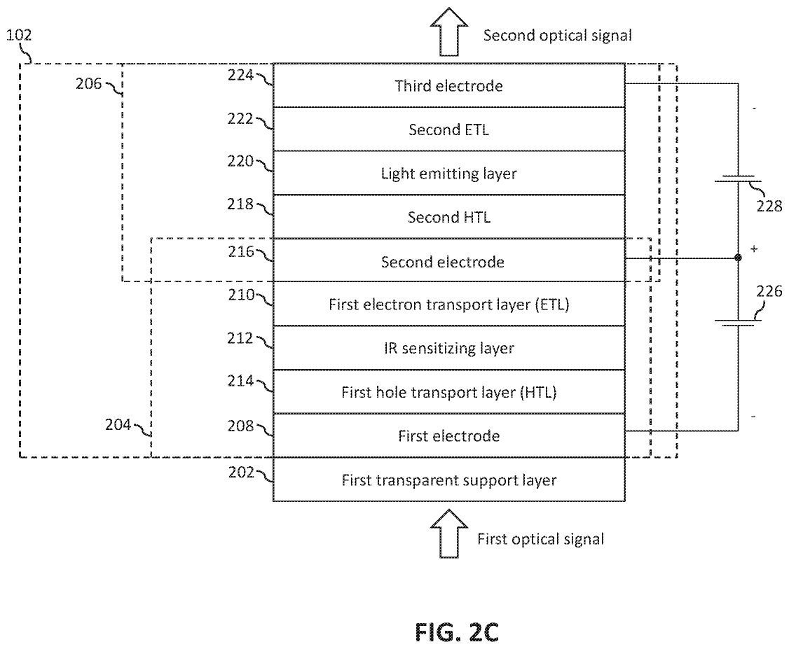

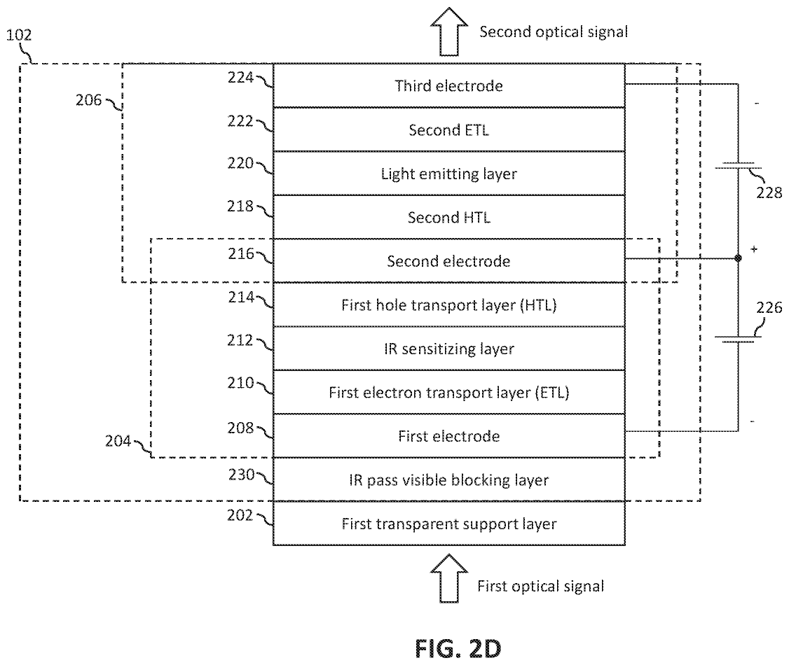

The up-conversion device 102 receives a first optical signal at a first wavelength from an object that is to be imaged. The up-conversion device 102 upconverts the first optical signal to a second optical signal having a second wavelength such that the first wavelength is greater than the second wavelength. In an example, the first optical signal is infrared (IR) light and the second optical signal is visible light. In an embodiment, lenses (not shown) are attached to the up-conversion device 102 for focusing the first optical signal onto the up-conversion device 102. In another embodiment, light filters (not shown) are attached to the up-conversion device 102 for focusing the first optical signal onto the up-conversion device 102. The up-conversion device 102 is explained in conjunction with FIGS. 2A-2D.

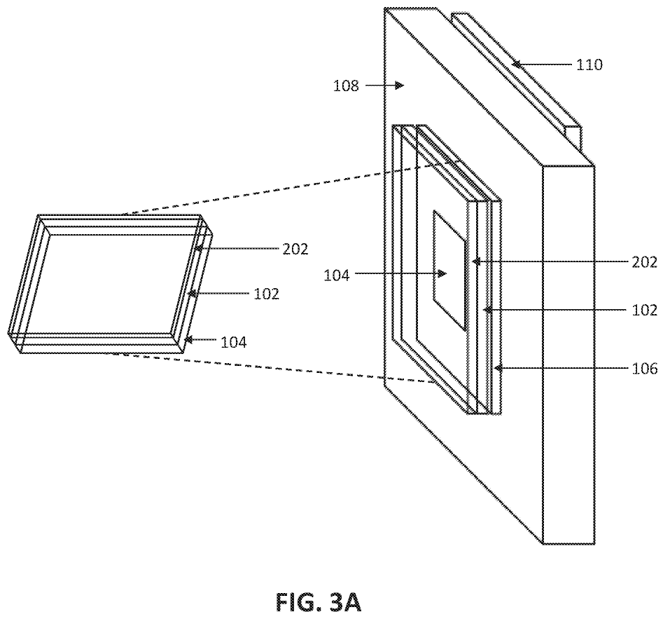

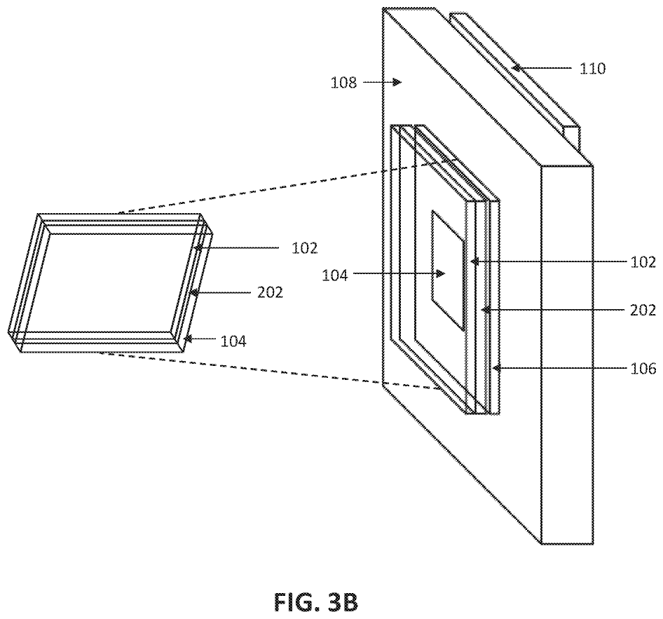

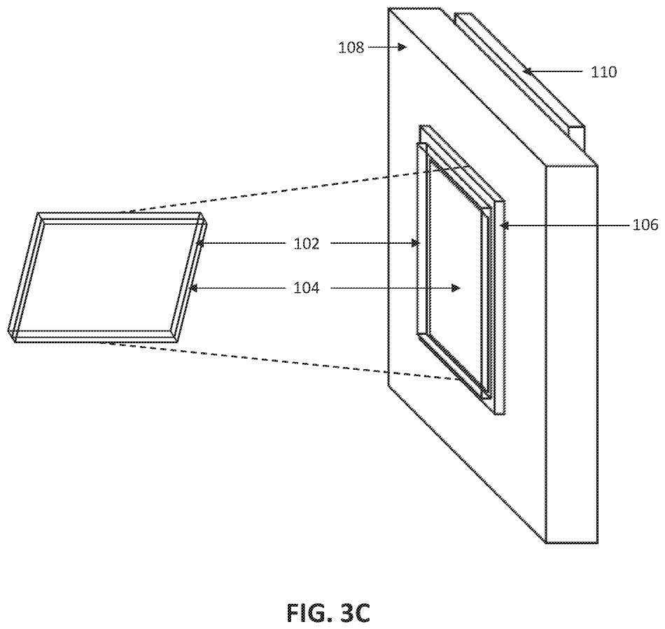

The image sensor 104 receives the second optical signal from the up-conversion device 102. The connection of the up-conversion device 102 with the image sensor 104 is explained in conjunction with FIGS. 3A-3C. The image sensor 104 includes pixels (not shown) having a photodetector (not shown). The pixels may further include at least one amplifier (not shown). The photodetector thus receives, i.e., detects the second optical signal which is received by the image sensor 104 and outputs an electrical signal. The amplifier may further amplify the electrical signal.

The electronic system 108 is connected to the image sensor 104 by way of the PCB 106 for receiving the electrical signal and outputs an image of the object based on the electrical signal. It will be apparent to a person skilled in the art that the electronic system 108 may output a live, continuous, or semi-continuous collection of images in video format. The electronic system 108 may include processors (not shown), transceivers (not shown) and a memory (not shown). The display 110 displays the image generated by the electronic system 108. Examples of the display 110 include, but are not limited to, a thin film transistor liquid crystal display (TFT LCD), an in-plane switching (IPS) LCD, a Resistive Touchscreen LCD, a Capacitive Touchscreen LCD, a Retina Display, and a Haptic/Tactile touchscreen.

FIG. 2A illustrates the up-conversion device 102 of the imaging device 100, in accordance with an embodiment of the present invention. The up-conversion device 102 is formed on a first transparent support layer 202. Examples of the first transparent support layer 202 include, but are not limited to, rigid materials such as glass, and flexible materials such as organic polymer. The up-conversion device 102 includes a light detecting device 204 and a light emitting device 206.

The light detecting device 204 receives the first optical signal and generates hole and electron photocurrents. The light detecting device 204 includes a first electrode 208, a first electron transport layer (ETL) 210, an infrared (IR) sensitizing layer 212, a first hole transport layer (HTL) 214, and a second electrode 216. In a preferred embodiment, the light detecting device 204 is a photodiode. In other embodiments, the light detecting device 204 may be a solar cell, a light dependent resistor, a phototransistor, or the like.

The light emitting device 206 is formed on the light detecting device 204. The light emitting device 206 receives the hole or electron photocurrents and outputs the second optical signal. The second electrode 216 is a common electrode between the light detecting device 204 and the light emitting device 206. Alternatively stated, the light detecting device 204 and the light emitting device 206 share the second electrode 216. The up-conversion device 102 is thus a common base (CB) transistor, where the second electrode 216 is a base of the CB transistor, the light detecting device 204 is an emitter of the CB transistor, and the light emitting device 206 is a collector of the CB transistor.

The light emitting device 206 includes a second HTL 218, a light emitting layer 220, a second ETL 222, and a third electrode 224. In an embodiment, the light emitting device 206 is an organic light emitting diode (LED). In another embodiment, the light emitting device 206 is an inorganic LED.

The first electrode 208 is formed on the first transparent support layer 202. The first electrode 208 may include indium tin oxide (ITO), indium zinc oxide (IZO), aluminum (Al), aluminum tin oxide (ATO), aluminum zinc oxide (AZO), silver (Ag), magnesium (Mg), Ag:Mg, carbon nanotubes, silver nanowires, or the like. The first electrode 208 may be translucent or transparent.

The first ETL 210 is formed on the first electrode 208. In an embodiment, the first ETL 210 may be an inorganic ETL including zinc oxide (ZnO), titanium dioxide (TiO₂), or the like. In another embodiment, the first ETL 210 may be an organic ETL including, for example, 2,9-Dimethyl-4,7-diphenyl-1,10-phenanthroline (BCP), p-bis(triphenylsityl)benzene (UGH2), 4,7-diphenyl-1,10-phenanthroline (BPhen), tris-(8-hydroxy quinoline) aluminum (Alq₃), 3,5′-N,N′-dicarbazole-benzene (mCP), tris[3-(3-pyridyl)-mesityl]borane (3TPYMB), or the like.

The IR sensitizing layer 212 is formed on the first ETL 210. In an embodiment, the IR sensitizing layer 212 may be a broad-spectrum absorption IR sensitizing layer including colloidal lead selenide (PbSe) quantum dots (QDs), colloidal lead sulfide (PbS) QDs, or colloidal mercury telluride (HgTe) QDs. In another embodiment, the IR sensitizing layer 212 may include a continuous thin film of PbSe, PbS, HgTe, indium arsenide (InAs), indium gallium arsenide (InGaAs), silicon (Si), germanium (Ge), or gallium arsenide (GaAs). In yet another embodiment, the IR sensitizing layer 212 may be an organic or organometallic comprising material, such as, but not limited to, perylene-3,4,9,10-tetracarboxylic-3,4,9,10-dianhydride (PTCDA), tin (II) phthalocyanine (SnPc), SnPc:C₆₀, aluminum phthalocyanine chloride (AlPcCl), AlPcCl:C₆₀, titanyl phthalocyanine (TiOPc), and TiOPc:C₆₀.

The first HTL 214 is formed on the IR sensitizing layer 212. The first HTL 214 may include molybdenum oxide (MoOₓ), 1,1-bis[(di-4-tolylamino)phenyl]cyclohexane (TAPC), N,N′-diphenyl-N,N′(2-naphthyl)-(1,1′-phenyl)-4,4′-diamine (NPB), N,N′-diphenyl-N,N′-di(m-tolyl) benzidine (TPD), or the like.

The second electrode 216 is formed on the first HTL 214. The second electrode 216 may include Al, Ag, Mg, Ag:Mg, ITO, IZO, ATO, AZO, carbon nanotubes, silver nanowires, or the like. The second electrode 216 may be translucent or transparent.

The second HTL 218 is formed on the second electrode 216. The second HTL 218 may include MoOₓ, TAPC, NPB, TPD, or the like.

The light emitting layer 220 is formed on the second HTL 218. The light emitting layer 220 may be an organic light emitting layer including bis[2-(2-pyridinyl-N)phenyl-C](acetylacetonato)iridium(III) (Ir(ppy)₂acac) or fac-tris(2-phenylpyridine)iridium (Ir(ppy)₃). Other light emitting materials that may be employed in the light emitting layer 220 include, but are not limited to, poly-[2-methoxy, 5-(2′-ethyl-hexyloxy) phenylene vinylene] (MEH-PPV), tris-(8-hydroxy quinoline) aluminum (Alq₃), and iridium (III) bis-[(4,6-di-fluorophenyl)-pyridinate-N,C2′]picolinate (FIrpic).

The second ETL 222 is formed on the light emitting layer 220. In an embodiment, the second ETL 222 may be an inorganic ETL that includes ZnO, TiO₂, or the like. In another embodiment, the second ETL 222 may be an organic ETL that includes BCP, UGH2, BPhen, Alq₃, mCP, 3TPYMB, or the like.

The third electrode 224 is formed on the second ETL 222. The third electrode 224 may include Al, Ag, Mg, calcium (Ca), lithium fluoride (LiF), ITO, IZO, ATO, AZO, carbon nanotube, silver nanowire, Ag:Mg, Mg:Al, LiF/Al/ITO, Ag/ITO, CsCO₃/ITO, LiF/Ag, or the like. The third electrode 224 may be translucent or transparent. In an embodiment, a second transparent support layer (not shown) is formed on the third electrode 224. The second transparent support layer may be glass or organic polymer.

The up-conversion device 102 is connected to first and second voltage supplies 226 and 228. The first voltage supply 226 is connected between the first electrode 208 and the second electrode 216. The second voltage supply 228 is connected between the second electrode 216 and the third electrode 224. In an embodiment, the light detecting device 204 is reverse biased and the light emitting device 206 is forward biased. Thus, the first and third electrodes 208 and 224 are negatively biased such that the first and third electrodes 208 and 224 are cathodes, and the second electrode 216 is positively biased such that the second electrode 216 is an anode.

In operation, the up-conversion device 102 receives the first optical signal at the first wavelength from the object. When the first optical signal is incident on the IR sensitizing layer 212 by way of the first electrode 208, charge carriers, such as holes and electrons are generated. Since the light detecting device 204 is reverse biased, the holes and electrons drift towards the second electrode 216 and the first electrode 208, thereby generating hole and electron photocurrents, respectively. The first ETL 210 allows the passage of the electrons (i.e., electron photocurrent) from the IR sensitizing layer 212 to the first electrode 208. The first HTL 214 allows the passage of the holes (i.e., hole photocurrent) from the IR sensitizing layer 212 to the second electrode 216. The second electrode 216 further injects holes into the light emitting device 206 due to the biasing of the light emitting device 206. Thus, the holes (i.e., hole photocurrent) from the IR sensitizing layer 212 and the holes injected from the second electrode 216 are transported into the light emitting layer 220 by way of the second HTL 218.

The third electrode 224 injects electrons into the light emitting device 206 due to the biasing of the light emitting device 206. The electrons from the third electrode 224 are transported into the light emitting layer 220 by way of the second ETL 222. The holes and electrons transported into the light emitting layer 220 combine to form the second optical signal. Thus, the light emitting layer 220 outputs the second optical signal based on the first optical signal and the biasing of the light detecting and light emitting devices 204 and 206.

The second optical signal passes through the third electrode 224 and is received by the image sensor 104. The image sensor 104 outputs the electrical signal based on the second optical signal. The electronic system 108 is connected to the image sensor 104 for receiving the electrical signal and outputs the image of the object based on the electrical signal. The display 110 displays the image generated by the electronic system 108.

It will be apparent to a person skilled in the art that when the first optical signal is visible light and is incident on the up-conversion device 102, the up-conversion device 102 outputs the second optical signal as the first optical signal.

FIG. 2B illustrates the up-conversion device 102, in accordance with another embodiment of the present invention. In the embodiment, the up-conversion device 102 is formed on the first transparent support layer 202. The third electrode 224 is formed on the first transparent support layer 202. The second ETL 222 is formed on the third electrode 224. The light emitting layer 220 is formed on the second ETL 222. The second HTL 218 is formed on the light emitting layer 220. The second electrode 216 is formed on the second HTL 218. The first HTL 214 is formed on the second electrode 216. The IR sensitizing layer 212 is formed on the first HTL 214. The first ETL 210 is formed on the IR sensitizing layer 212. The first electrode 208 is formed on the first ETL 210. In another embodiment, the second transparent support layer is formed on the first electrode 208. The up-conversion device 102 receives the first optical signal from the first electrode 208 and outputs the second optical signal from the first transparent support layer 202.

FIG. 2C illustrates the up-conversion device 102, in accordance with yet another embodiment of the present invention. In the embodiment, the up-conversion device 102 is formed on a first transparent support layer 202. The first electrode 208 is formed on the first transparent support layer 202. The first HTL 214 is formed on the first electrode 208. The IR sensitizing layer 212 is formed on the first HTL 214. The first ETL 210 is formed on the IR sensitizing layer 212. The second electrode 216 is formed on the first ETL 210. The formation of the second HTL 218, the light emitting layer 220, the second ETL 222, and the third electrode 224 has been explained in FIG. 2A. In an embodiment, the second transport support layer is formed on the third electrode 224.

In operation, the up-conversion device 102 receives the first optical signal at the first wavelength from the object. When the first optical signal is incident on the IR sensitizing layer 212 by way of the first electrode 208, charge carriers, such as holes and electrons are generated. The holes and the electrons drift towards the first electrode 208 and the second electrode 216, thereby generating hole and electron photocurrents, respectively. The first HTL 214 allows the passage of the holes (i.e., hole photocurrent) from the IR sensitizing layer 212 to the first electrode 208. The first ETL 210 allows the passage of the electrons (i.e., electron photocurrent) from the IR sensitizing layer 212 to the second electrode 216. The collected electrons at the second electrode 216 pass through the first voltage supply 226 due to the biasing of the light detecting device 204. The functions performed by the second electrode 216, the second HTL 218, the light emitting layer 220, the second ETL 222, and the third electrode 224 are similar to the functions performed by the stated layers in FIG. 2A.

FIG. 2D illustrates the up-conversion device 102 that includes an IR pass visible blocking layer 230, in accordance with yet another embodiment of the present invention. In the embodiment, the IR pass visible blocking layer 230 is formed between the first transparent support layer 202 and the first electrode 208. The IR pass visible blocking layer 230 passes the first optical signal (IR light) from the first transparent support layer 202 to the first electrode 208 and blocks the passage of the second optical signal (visible light) from the first electrode 208 to the first transparent support layer 202 by absorbing or reflecting the second optical signal. Thus, the IR pass visible blocking layer 230 may have a reflecting or a non-reflecting surface. In another embodiment, the first transparent support layer 202 may be formed directly on the IR pass visible blocking layer 230, and the first electrode 208 is formed on the first transparent support layer 202. In yet another embodiment, the IR pass visible blocking layer 230 may be formed on any of the first electrode 208, the first ETL 210, the IR sensitizing layer 212, the first HTL 214, and the second electrode 216. The IR pass visible blocking layer 230 are typically employed in up-conversion devices for night vision devices, as it is desirable to block the emission of the second optical signal (visible light) from a direction where the first optical signal is received by the up-conversion device 102. It will be apparent to a person skilled in the art that the IR pass visible blocking layer 230 may be employed in the up-conversion device 102 of FIG. 2B and may be formed on the first electrode 208, the first ETL 210, the IR sensitizing layer 212, the first HTL 214, and the second electrode 216.

The IR pass visible blocking layer 230 may employ a dielectric stack layer with alternating films having alternating refractive indices, where films of a higher refractive index (RI) alternate with films of a significantly lower refractive index. In an example, the IR pass visible blocking layer 230 may be formed from a composite of alternating tantalum pentaoxide (Ta₂O₅) films (R2.1) and silicon dioxide (SiO₂) films (RI=1.45), a composite of alternating titanium dioxide (TiO₂) films and SiO₂ films, a composite of alternating LiF films and tellurium dioxide (TeO₂) films, or the like. In another example, the IR pass visible blocking layer 230 may be formed from one or more films that inherently have high IR transparency but are opaque to visible light such as cadmium sulfide (CdS), indium phosphide (InP), or cadmium telluride (CdTe).

FIG. 3A illustrates the construction of the imaging device 100, in accordance with an embodiment of the present invention. To form the imaging device 100 as shown in FIG. 3A, the up-conversion device 102 is formed on the first transparent support layer 202 (as shown in the up-conversion device 102 of FIG. 2A) and is connected to the image sensor 104 such that the image sensor 104 is in direct contact with the up-conversion device 102. When the first transparent support layer 202 is a glass substrate, the up-conversion device 102 is connected to the image sensor 104 by way of mechanical fasteners or adhesives. When the first transparent support layer 202 is a flexible film, such as organic polymer, the up-conversion device 102 is formed on the flexible film and is subsequently laminated to the image sensor 104.

FIG. 3B illustrates the construction of the imaging device 100, in accordance with another embodiment of the present invention. To form the imaging device 100 as shown in FIG. 3B, the up-conversion device 102 is formed on the first transparent support layer 202 (as shown in the up-conversion device 102 of FIG. 2B) and is connected to the image sensor 104 such that the first transparent support layer 202 is in direct contact with the image sensor 104. When the first transparent support layer 202 is a glass substrate, the first transparent support layer 202 is connected to the image sensor 104 by way of mechanical fasteners or adhesives. When the first transparent support layer 202 is a flexible film, such as organic polymer, the up-conversion device 102 is formed on the flexible film and is subsequently laminated to the image sensor 104.

FIG. 3C illustrates the construction of the imaging device 100, in accordance with yet another embodiment of the present invention. The up-conversion device 102 is formed on the image sensor 104 such that the third electrode 224 is in direct contact with the image sensor 104.

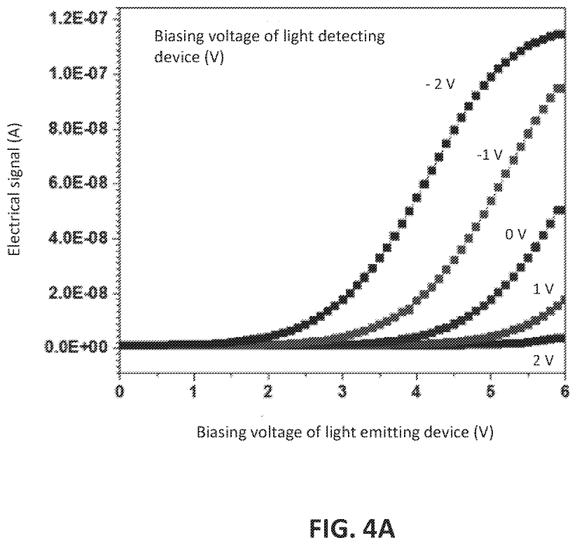

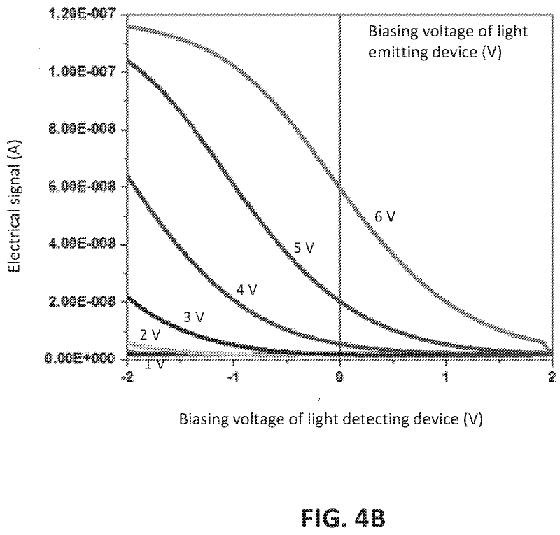

FIG. 4A illustrates a graph showing a current-voltage (I-V) curve of the electrical signal and a biasing voltage of the light emitting device 206 for various biasing voltages of the light detecting device 204, in accordance with an embodiment of the present invention. FIG. 4B illustrates a graph showing the I-V curve of the electrical signal and a biasing voltage of the light detecting device 204 for various biasing voltages of the light emitting device 206, in accordance with an embodiment of the present invention.

As shown in FIG. 4A, when the light detecting device 204 is reverse biased, i.e., when the biasing voltage of the light detecting device 204 is less than 0 volts (V), the light emitting device 206 is switched ON at lower biasing voltages of the light emitting device 206. When the light detecting device 204 is forward biased, i.e., when the biasing voltage of the light detecting device 204 is greater than 0 V, the light emitting device 206 is switched ON at higher biasing voltages of the light emitting device 206. Thus, photon-to-photon conversion efficiency (i.e., conversion of the first optical signal to the second optical signal) of the up-conversion device 102 improves when the light detecting device 204 is reverse biased.

As shown in FIG. 4B, for a constant biasing voltage of the light emitting device 206, in an example (4V), when the biasing voltage of the light detecting device 204 is reduced, an amplitude of the electrical signal increases. Thus, a desired amplitude of the electrical signal is achieved by controlling the biasing voltage of the light detecting device 204.

Since the up-conversion device 102 is a three-terminal up-conversion device, the up-conversion device 102 provides an improved control of the injection of charge carriers in the light emitting layer 220 even when the IR light has low intensity. This increases sensitivity of the up-conversion device 102 due to the positively biased second electrode 216 that controls the injection of charge carriers as compared to convention up-conversion devices. Thus, a desired amplitude of the electrical signal is achieved by the imaging device 100 which further improves the image quality.

It will be apparent to a person skilled in the art that the up-conversion device 102 is not limited for use in the imaging device 100. The up-conversion device 102 may also be used in other devices or systems such as light detection and ranging (LIDAR).

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. An up-conversion device, comprising:
a light detecting device that comprises a first electrode, a first electron transport layer, an infrared (IR) sensitizing layer, a first hole transport layer, and a second electrode, wherein the light detecting device receives a first optical signal at a first wavelength; and
a light emitting device that is formed on the light detecting device, and shares the second electrode with the light detecting device, wherein the light emitting device includes a second hole transport layer, a light emitting layer, a second electron transport layer, and a third electrode, and wherein the light emitting device outputs a second optical signal at a second wavelength based on the first optical signal and biasing of the light detecting device and the light emitting device.

2. The up-conversion device of claim 1, wherein:
the first electron transport layer is formed on the first electrode,
the IR sensitizing layer is formed on the first electron transport layer,
the first hole transport layer is formed on the IR sensitizing layer,
the second electrode is formed on the first hole transport layer,
the second hole transport layer is formed on the second electrode,
the light emitting layer is formed on the second hole transport layer,
the second electron transport layer is formed on the light emitting layer, and
the third electrode is formed on the second electron transport layer.

3. The up-conversion device of claim 1, wherein:
the second electron transport layer is formed on the third electrode,
the light emitting layer is formed on the second electron transport layer,
the second hole transport layer is formed on the light emitting layer,
the second electrode is formed on the second hole transport layer,
the first hole transport layer is formed on the second electrode,
the IR sensitizing layer is formed on the first hole transport layer,
the first electron transport layer is formed on the IR sensitizing layer, and
the first electrode is formed on the first electron transport layer.

4. The up-conversion device of claim 1, wherein:
the first hole transport layer is formed on the first electrode,
the IR sensitizing layer is formed on the first hole transport layer,
the first electron transport layer is formed on the IR sensitizing layer,
the second electrode is formed on the first electron transport layer,
the second hole transport layer is formed on the second electrode,
the light emitting layer is formed on the second hole transport layer,
the second electron transport layer is formed on the light emitting layer, and
the third electrode is formed on the second electron transport layer.

5. The up-conversion device of claim 1, wherein the first through third electrodes comprise indium tin oxide (ITO), indium zinc oxide (IZO), aluminum (Al), aluminum tin oxide (ATO), aluminum zinc oxide (AZO), silver (Ag), magnesium (Mg), Ag:Mg, carbon nanotubes, or silver nanowires.

6. The up-conversion device of claim 1, wherein the first and second electron transport layers comprise zinc oxide (ZnO), titanium dioxide (TiO₂), 2,9-Dimethyl-4,7-diphenyl-1,10-phenanthroline (BCP), p-bis(triphenylsityl)benzene (UGH2), 4,7-diphenyl-1,10-phenanthroline (BPhen), tris-(8-hydroxy quinoline) aluminum (Alq₃), 3,5′-N,N′-dicarbazole-benzene (mCP), or tris[3-(3-pyridyl)-mesityl]borane (3TPYMB).

7. The up-conversion device of claim 1, wherein the first and second hole transport layers comprise molybdenum oxide (MoOₓ), 1,1-bis[(di-4-tolylamino)phenyl]cyclohexane (TAPC), N,N′-diphenyl-N,N′(2-naphthyl)-(1,1′-phenyl)-4,4′-diamine (NPB), or N,N′-diphenyl-N,N′-di(m-tolyl) benzidine (TPD).

8. The up-conversion device of claim 1, wherein the IR sensitizing layer comprises colloidal lead selenide (PbSe) quantum dots (QDs), colloidal lead sulfide (PbS) QDs, colloidal mercury telluride (HgTe) QDs, PbSe film, PbS film, HgTe film, indium arsenide (InAs) film, indium gallium arsenide (InGaAs) film, silicon (Si) film, germanium (Ge) film, gallium arsenide (GaAs) film, perylene-3,4,9,10-tetracarboxylic-3,4,9,10-dianhydride (PTCDA), tin (II) phthalocyanine (SnPc), SnPc:C₆₀, aluminum phthalocyanine chloride (AlPcCl), AlPcCl:C₆₀, titanyl phthalocyanine (TiOPc), or TiOPc:C₆₀.

9. The up-conversion device of claim 1, wherein the light emitting layer comprises bis[2-(2-pyridinyl-N)phenyl-C](acetylacetonato)iridium(III) (Ir(ppy)₂acac), fac-tris(2-phenylpyridine)iridium (Ir(ppy)₃), poly-[2-methoxy, 5-(2′-ethyl-hexyloxy) phenylene vinylene] (MEH-PPV), tris-(8-hydroxy quinoline) aluminum (Alq₃), or iridium (III) bis-[(4,6-di-fluorophenyl)-pyridinate-N,C2′]picolinate (FIrpic).

10. The up-conversion device of claim 1, wherein the up-conversion device is a common-base (CB) transistor with the second electrode as a base of the CB transistor, the light detecting device as an emitter of the CB transistor, and the light emitting device as a collector of the CB transistor.

11. The up-conversion device of claim 1, wherein the light detecting device is reverse biased and the light emitting device is forward biased such that the first and third electrodes are cathodes and the second electrode is an anode.

12. The up-conversion device of claim 1, wherein the IR sensitizing layer receives the first optical signal at the first wavelength and generates hole and electron photocurrents.

13. The up-conversion device of claim 12, wherein the light emitting layer receives one of the hole and electron photocurrents and outputs the second optical signal at the second wavelength, and wherein the first wavelength is greater than the second wavelength.

14. The up-conversion device of claim 1, wherein the light detecting device is a photodiode and the light emitting device is at least one of an organic light emitting diode or an inorganic light emitting diode.

15. The up-conversion device of claim 1, wherein the up-conversion device is connected to an image sensor that receives the second optical signal and outputs an electrical signal, and wherein the up-conversion device and the image sensor form an imaging device.

16. The up-conversion device of claim 15, wherein the up-conversion device is formed on at least one of a transparent support layer or the image sensor.

17. The up-conversion device of claim 16, further comprising an IR pass visible blocking layer that is formed between the transparent support layer and the first electrode, wherein the IR pass visible blocking layer comprises alternating layers of materials having alternating refractive indices.

18. An imaging device, comprising:
an up-conversion device, comprising:
a light detecting device that comprises a first electrode, a first electron transport layer, an infrared (IR) sensitizing layer, a first hole transport layer, and a second electrode, wherein the light detecting device receives a first optical signal at a first wavelength; and
a light emitting device that is formed on the light detecting device, and shares the second electrode with the light detecting device, wherein the light emitting device includes a second hole transport layer, a light emitting layer, a second electron transport layer, and a third electrode, and wherein the light emitting device outputs a second optical signal at a second wavelength based on the first optical signal and biasing of the light detecting device and the light emitting device; and
an image sensor connected to the up-conversion device, wherein the image sensor receives the second optical signal and outputs an electrical signal.

19. The imaging device of claim 18, wherein:
the first electron transport layer is formed on the first electrode,
the IR sensitizing layer is formed on the first electron transport layer,
the first hole transport layer is formed on the IR sensitizing layer,
the second electrode is formed on the first hole transport layer,
the second hole transport layer is formed on the second electrode,
the light emitting layer is formed on the second hole transport layer,
the second electron transport layer is formed on the light emitting layer, and
the third electrode is formed on the second electron transport layer.

20. The imaging device of claim 18, wherein:
the second electron transport layer is formed on the third electrode,
the light emitting layer is formed on the second electron transport layer,
the second hole transport layer is formed on the light emitting layer,
the second electrode is formed on the second hole transport layer,
the first hole transport layer is formed on the second electrode,
the IR sensitizing layer is formed on the first hole transport layer,
the first electron transport layer is formed on the IR sensitizing layer, and
the first electrode is formed on the first electron transport layer.
